(19) United States
(12) Patent Application Publication
(10) Pub. No.: US 2009/0087978 A1
(43) Pub. Date: Apr. 2, 2009

(54) INTERCONNECT MANUFACTURING PROCESS

(75) Inventors: Chao-Wen Lay, Miaoli County (TW); Jen-Jui Huang, Taoyuan County (TW)

Correspondence Address: J C PATENTS, INC., 4 VENTURE, SUITE 250, IRVINE, CA, 92618, US

(73) Assignee: NANYA TECHNOLOGY CORPORATION

(21) Appl. No.: 11/958,974

(22) Filed: Dec. 18, 2007

(30) Foreign Application Priority Data
Oct. 1, 2007 (TW) 96136780

(51) Int. Cl. H01L 21/4763

(52) U.S. Cl. 438/618; 257/E21.495

(57) ABSTRACT

An interconnect process is provided. A substrate is provided. A plurality of gate structures is disposed on the substrate, and doped regions are disposed in the substrate and respectively located between two adjacent gate structure. A liner is conformally formed above the substrate. A dielectric layer is formed above the substrate. A contact opening is formed in the dielectric layer between two neighboring gate structures to expose the liner on the doped region and on a portion of the top surface and a portion of the sidewall of each of the gate structures. A polymer material is deposited on the liner on the portion of the top surface of each of the gate structures and on the doped region. The liner on the doped regions is removed. A conductive layer is filled in the contact opening, which is free of electrical connection to the gate structures.

### CROSS-REFERENCE TO RELATED APPLICATION

This application claims the priority benefit of Taiwan application serial no. 96136780, filed on Oct. 1, 2007. The entirety of the above-mentioned patent application is hereby incorporated by reference herein and made a part of this specification.

### BACKGROUND OF THE INVENTION

1. Field of the Invention

The present invention relates to a semiconductor manufacturing process, and more particularly to an interconnect manufacturing process.

2. Description of Related Art

With the progress of semiconductor technology, devices gradually become smaller than ever. When integrity of an integrated circuit (IC) is increased, a surface of a chip cannot provide enough area for placing the required interconnects. In order to meet the requirements of the increased interconnects after the sizes of devices are reduced, a design of multi-layer metal interconnect structure having more than two layers has been inevitably adopted in Very Large Scale Integrated Circuit (VLSI) technology. As for the current process for forming metal interconnect, damascene technique is always adopted.

FIGS. 1A to 1D are cross-sectional views of processes of a conventional interconnect manufacturing process.

First, referring to FIG. 1A, a substrate 100 is provided. The substrate 100 has gate structures 102 thereon. Each of the gate structures 102 includes a gate dielectric layer 102a located on the substrate 100 and a gate 102b located on the gate dielectric layer 102a. Moreover, a doped region 104 is disposed in the substrate 100 at two sides of each gate structure 102, so as to serve as a source/drain region.

Referring to FIG. 1B, a liner 110 is conformally formed on the substrate 100. The liner 110 covered on the surface of each gate structure 102 prevents the gate structures 102 from being in contact with a subsequently formed contact to cause short circuit. Thereafter, a dielectric layer 106 is formed on the substrate 100. The dielectric layer 106 covers the gate structures 102 and the doped region 104. Then, a photolithography process and an etching process are performed, so as to form a contact opening 108 in the dielectric layer 106 between two neighboring gate structures 102. The contact opening 108 exposes the liner 110 on the doped region 104 and on a portion of the top surface and a portion of the side wall of the gate structures 102.

Referring to FIG. 1C, a dry etching process is performed to remove the liner 110 above the doped region 104, so as to expose the doped region 104. The exposed doped region 104 may be electrically connected to a subsequently formed contact.

Referring to FIG. 1D, a conductive layer 114 is formed in the contact opening 108. The conductive layer 114 is electrically connected to the doped region 104, so as to serve as the contact in the interconnect, thereby finishing the fabrication of the interconnect.

However, in the steps of FIG. 1C, when performing the dry etching process, not only the liner 110 above the doped region 104, but also the liner 110 on the gates 102b is removed. Moreover, in order to completely remove the liner 110 above the doped region 104, over etching usually occurs. Consequently, a portion of the liner 110 on sidewall of the gates 102b is also removed, thus exposing a corner 112 of the gates 102b. Therefore, in FIG. 1D, when forming the conductive layer 114 in the contact opening 108, the conductive layer 114 is electrically connected to the doped region 104, and additionally, the conductive layer 114 is in contact with the gates 102b at the corner 112, which leads to short circuit.

In order to avoid the above problems, the above dry etching process is generally controlled to some extent, so as not to expose the gates 102b after the liner 110 above the doped region 104 is completely removed. However, the process window is always too narrow, thus increasing the process difficulty.

### SUMMARY OF THE INVENTION

Accordingly, the present invention is directed to an interconnect process, which prevents a contact from being in contact with a gate to cause short circuit, and also increase process windows of a dry etching process during the process of performing the dry etching process to expose the doped region.

The present invention provides an interconnect process, which includes the following steps. First, a substrate is provided. The substrate has a plurality of gate structures thereon, and doped regions are disposed in the substrate and respectively located between two adjacent gate structures. A liner is conformally formed above the substrate. A dielectric layer is formed above the substrate. A contact opening is formed in the dielectric layer between two neighboring gate structures, so as to expose the liner on the doped region and on a portion of the top surface and a portion of the sidewall of each of the gate structures. A polymer material is deposited on the liner on the portion of the top surface of each of the gate structures and on the doped regions. The liner on the doped regions is removed. A conductive layer is filled in the contact opening, which is free of electrical connection to the gate structures.

In the interconnect process according to an embodiment of the present invention, the polymer material on the gate structures has a thickness greater than that of the polymer material on the doped region, for example.

In the interconnect process according to an embodiment of the present invention, a gas used in depositing the polymer material is, for example, silicon-containing gas.

In the interconnect process according to an embodiment of the present invention, the silicon-containing gas is, for example, silicon fluoride, silicon chloride, or silicon bromide.

In the interconnect process according to an embodiment of the present invention, the liner is made of, for example, silicon oxide.

In the interconnect process according to an embodiment of the present invention, the liner is formed by, for example, a chemical vapor deposition (CVD) process.

In the interconnect process according to an embodiment of the present invention, a material of the dielectric layer is, for example, silicon oxide.

In the interconnect process according to an embodiment of the present invention, the dielectric layer is formed by, for example, a CVD process.

In the interconnect process according to an embodiment of the present invention, a process of depositing the polymer material is, for example, performed by adjusting process parameters of an etching machine.

In the present invention, before performing the dry etching process to expose the doped region, a polymer material is first deposited on a spacer material layer or liner on the gate structures and on the doped region. The thickness of the polymer material on the gate structures is greater than the thickness of the polymer material on the doped region after adjusting the process parameters. Therefore, after performing the dry etching process, the gates will not be exposed, thereby avoiding the gates from being in contact with the contact plug to cause short circuit.

Moreover, during the above dry etching process, it is unnecessary to accurately control the dry etching process to some extent that the film layer on the doped region is completely removed without exposing the gates, so as to achieve the purpose of increasing process window.

In order to make the aforementioned and other objects, features and advantages of the present invention comprehensible, preferred embodiments accompanied with figures is described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to describe the principles of the invention.

FIGS. 1A to 1D are sectional views of processes of a conventional interconnect process.

FIG. 2A to 2D are sectional views of processes of an interconnect process according to an embodiment of the present invention.

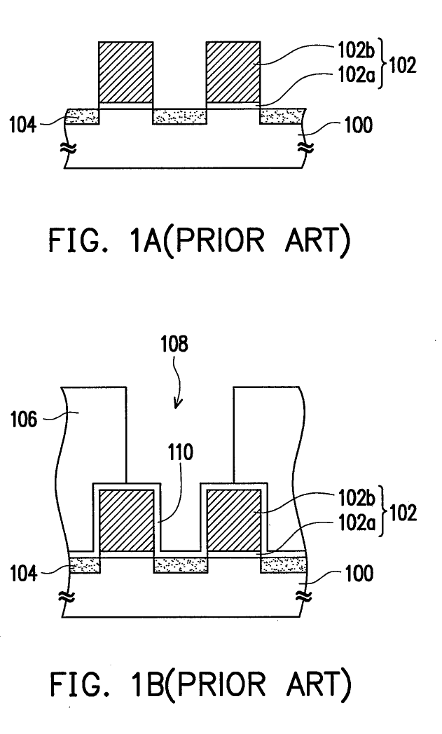

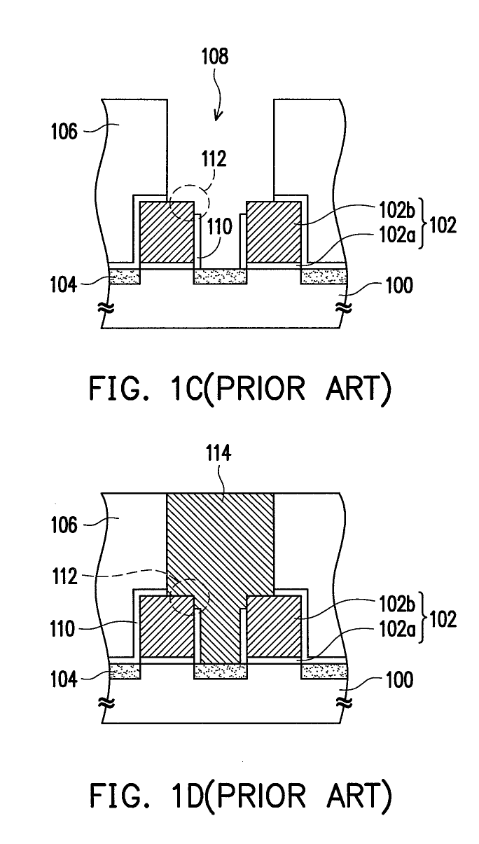

### DESCRIPTION OF EMBODIMENTS

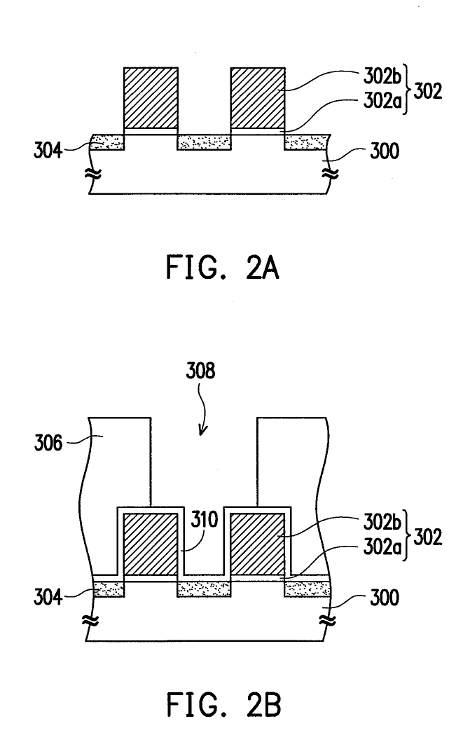

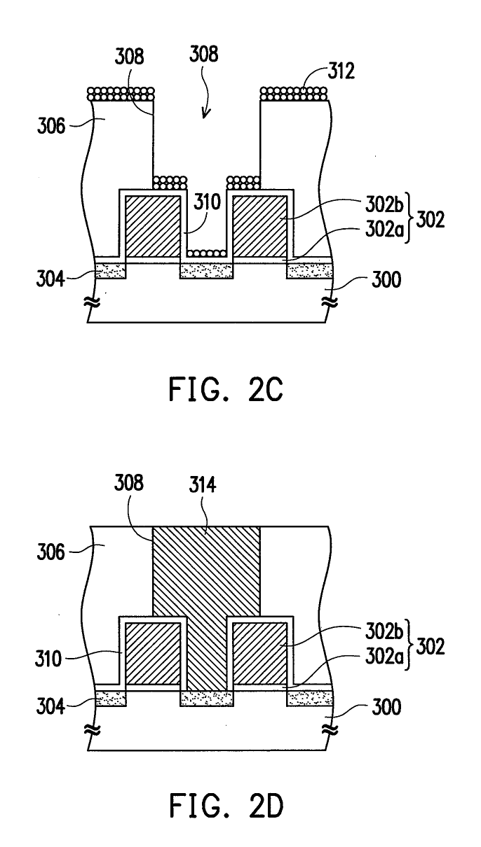

FIGS. 2A to 2D are cross-sectional views of processes of the interconnect process according to an embodiment of the present invention.

First, referring to FIG. 2A, a substrate 300 is provided. The substrate 300 has gate structures 302 thereon. Each of the gate structure 302 includes a gate dielectric layer 302a located on the substrate 300 and a gate 302b located on the gate dielectric layer 302a. Moreover, doped regions 304 are disposed in the substrate 300 and respectively located between two adjacent gate structures 302, so as to serve as a source/drain region.

Referring to FIG. 2B, a liner 310 is conformally formed on the substrate 300. The material of the liner 310 is, for example, silicon oxide, and the liner 310 is formed by, for example, a chemical vapor deposition (CVD) process. A dielectric layer 306 is formed on the substrate 300. The material of the dielectric layer 306 is, for example, silicon oxide, and the dielectric layer 306 is formed by, for example, a CVD process. A photolithography process and an etching process are preformed, so as to form a contact opening 308 in the dielectric layer 306 between two neighboring gate structures 302, thereby exposing the liner 310 on the doped regions 304 and on a portion of the top surface and a portion of the sidewall of the gate structures 302.

Referring to FIG. 2C, a polymer material 312 is deposited on liner 310 on the portion of the top surface of each the gate structures 302 and on the doped regions 304, in which the thickness of the polymer material 312 on the gate structures 302 is, for example, greater than the thickness of the polymer material 312 on the doped regions 304, so as to prevent the polymer material 312 on the gate structures 302 from being completely removed to expose the gates 302b in the subsequent etching process. Definitely, when the polymer material 312 is deposited on the liner 310 on the gate structures 302 and the doped regions 304, the polymer material 312 is also deposited on the dielectric layer 306.

In this embodiment, in the subsequent dry etching process, a silicon-containing gas such as silicon fluoride, silicon chloride, or silicon bromide is introduced in a dry etching machine, and process parameters are adjusted, so as to deposit the polymer material 312 on the liner 310 on the gate structures 302 and the doped regions 304. The thickness of the polymer material 312 on the gate structures 302 is greater than the thickness of the polymer material 312 on the doped regions 304 by adjusting the process parameter. Definitely, the polymer material 312 may be deposited on the liner 310 on the gate structures 302 and the doped regions 304 in a deposition machine, and then the subsequent etching process is performed in an etching machine.

Referring to FIG. 2D, for example, the dry etching process is performed to remove the polymer material 312 and the liner 310 on the doped regions 304, so as to expose the doped regions 304. Definitely, in the above steps, the polymer material 312 on the gate structures 302 is removed at the same time. A conductive layer 314 electrically connected to the doped regions 304 is formed in the contact opening 308, so as to serve as a contact plug, thereby completing the fabrication of the interconnect.

In the step of FIG. 2D, the thickness of the polymer material 312 on the gate structures 302 is greater than the thickness of the polymer material 312 on the doped regions 304. Thus, after performing the dry etching process to completely remove the polymer material 308 and the liner 310 on the doped regions 304, a portion of the polymer material 312 or the liner 310 is still remained on the gate structures 302, without exposing the gates 302b, thereby avoiding the gates 302b from being in contact with the conductive layer 314 to cause short circuit. Whether the polymer material 312 or the liner 310 is remained on the gate structures 302 depends on the difference between the thickness of the polymer material 312 on the gate structures 302 and the thickness of the polymer material 312 on the doped regions 304. That is to say, when the difference between the thickness of the polymer material 312 on the gate structures 302 and the thickness of the polymer material 312 on the doped regions 304 is great, the polymer material 312 and liner 310 will be remained on the gate structures 302. Otherwise, the liner 310 will be remained on the gate structures 302.

Moreover, in the above steps, it is unnecessary to accurately control the dry etching process to some extent that the film layer on the doped regions 304 is completely removed without exposing the gates 302b, so as to achieve the purpose of increasing process windows.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An interconnect manufacturing process, comprising:
providing a substrate having gate structures disposed on the substrate and doped regions disposed in the substrate and respectively located between two adjacent gate structures;
conformally forming a liner on the substrate;
forming a dielectric layer on the substrate;
forming a contact opening in the dielectric layer between two neighboring gate structures, so as to expose the liner on the doped region and on a portion of a top surface and a portion of the sidewall of each of the gate structures;
depositing a polymer material on the liner on the portion of the top surface of each of the gate structures and on the doped regions;
removing the liner on the doped regions; and
filling a conductive layer in the contact opening, which is free of electrical connection to the gate structures.

2. The interconnect process as claimed in claim 1, wherein a thickness of the polymer material on the gate structures is greater than a thickness of the polymer material on the doped region.

3. The interconnect process as claimed in claim 1, wherein a gas used in depositing the polymer material is a silicon-containing gas.

4. The interconnect process as claimed in claim 3, wherein the silicon-containing gas includes silicon fluoride, silicon chloride, silicon bromide.

5. The interconnect process as claimed in claim 1, wherein a material of the liner is silicon oxide.

6. The interconnect process as claimed in claim 1, wherein the liner is formed by a chemical vapor deposition (CVD) process.

7. The interconnect process as claimed in claim 1, wherein a material of the dielectric layer is silicon oxide.

8. The interconnect process as claimed in claim 1, wherein the dielectric layer is formed by a CVD process.

9. The interconnect process as claimed in claim 1, wherein a process of depositing the polymer material is performed by adjusting process parameters of a dry etching machine.
